(19) United States
(12) Patent Application Publication
(10) Pub. No.: US 2008/0239684 A1
(43) Pub. Date: Oct. 2, 2008

(54) WIRING BOARD AND METHOD OF MANUFACTURING THE SAME

(75) Inventor: Tomoo Yamasaki, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/059,223

(22) Filed: Mar. 31, 2008

(30) Foreign Application Priority Data
Apr. 2, 2007 (JP) 2007-096527
Feb. 6, 2008 (JP) 2008-026597

(51) Int. Cl. H05K 7/00; H01K 3/10

(52) U.S. Cl. 361/779; 29/850

(57) ABSTRACT

A wiring board including, on a resin insulating layer, an Ni—Cu alloy bonding seed layer constituted by 20 to 75 wt % of Ni and Cu to be a residual part and a wiring layer constituted by Cu formed thereon is provided. It is possible to manufacture the wiring board by (A) forming the Ni—Cu alloy bonding seed layer through a one-time treatment and removing an unnecessary portion through one-time etching after wiring patterning, or (B) forming the Ni—Cu alloy bonding seed layer and a Cu layer thereon and patterning thereof in a lump by etching. A wiring board in which a wiring layer is formed by an Ni—Cu alloy constituted by 20 to 75 wt % of Ni and Cu to be a residual part over a whole thickness of the wiring layer is also provided.

### BACKGROUND OF THE INVENTION

The present invention relates to a wiring board and a method of manufacturing the wiring board, and more particularly to a wiring board including a wiring layer capable of maintaining a bonding property to a resin insulating layer to be a ground without requiring a complicated step and a method of manufacturing the wiring board.

In a wiring board such as a semiconductor package, conventionally, a bonding layer constituted by a metal such as Ni, Ti, V, Nb, Ta, Cr, Mo or W or a Cu nitride is first formed on a surface of a resin layer and a Cu wiring layer is formed thereon in order to maintain a bonding property of a resin of an insulating layer to Cu of a wiring layer when the Cu wiring layer is to be formed on the resin insulating layer. By taking, as an example, the case in which Ni is used as a typical bonding layer, description will be given to a wiring forming process.

As shown in FIG. 1(1), a resin layer 10 constituted by epoxy having a thickness of approximately 50 μm is prepared as an interlayer insulating film of a wiring board, for example.

As shown in FIG. 1(2), a surface of the resin layer 10 is cleaned with an argon gas plasma and an Ni bonding layer 12 and a Cu seed layer 14 are sequentially formed through sputtering in an argon gas atmosphere of approximately 0.5 Pa with a vacuum held. For example, the Ni bonding layer 12 has a thickness of 50 nm and the Cu seed layer 14 has a thickness of 500 nm.

As shown in FIG. 1(3), a plated resist pattern 16 is formed on the Cu seed layer 14 through a photoresist application, a pattern exposure and a development.

As shown in FIG. 1(4), electrolytic Cu plating is carried out by using the Ni bonding layer 12/Cu seed layer 14 as a feeding layer, and an electrolytic Cu plated layer 18 is formed on the Cu seed layer 14 exposed into an opening of the plated resist pattern 16.

As shown in FIG. 1(5), the plated resist pattern 16 is peeled and removed.

As shown in FIG. 1(6), the Cu seed layer 14 in an unnecessary portion exposed through the peeling of the plated resist pattern 16 is removed with a sulfuric acid based etchant.

As shown in FIG. 1(7), the Ni bonding layer 12 in an unnecessary portion exposed by removing the Cu seed layer 14 is removed with a nitric acid based etchant. Consequently, there is finished a wiring layer 17 in a predetermined pattern which is constituted by the bonding layer 12, the seed layer 14 and the electrolytic Cu plated layer 18.

The Cu wiring layer 17 thus formed has a bonding property to the resin layer 10 maintained sufficiently through the Ni bonding layer 12.

However, a two-layer structure of the Ni bonding layer 12/Cu seed layer 14 has the following problems [1] and [2].

Problem [1]

In the case in which sputtering is carried out, for example, two targets are required for forming the Ni bonding layer 12 and the Cu seed layer 14. In consideration of a tact of a manufacturing process, furthermore, two sputtering chambers are required in some cases. Consequently, a manufacturing cost is increased.

Problem [2]

The Ni bonding layer 12 and the Cu seed layer 14 are to be removed with separate etchants. For this reason, it is necessary to carry out an etching treatment twice.

In order to eliminate the drawbacks, Patent Document 1 has proposed a method of forming a bonding layer with CuN.

Solution of Problem [1]

A nitrogen gas is introduced by using a Cu target to carry out reactive sputtering, thereby forming a CuN bonding layer. In the same treating chamber, successively, the introduction of the nitrogen gas is stopped to carry out sputtering using the same Cu target. Consequently, a Cu seed layer can be formed on the CuN bonding layer. Therefore, the manufacturing cost can be prevented from being increased.

Solution of Problem [2]

The CuN bonding layer and the Cu seed layer formed thereon can be removed with the same sulfuric acid based Cu etchant. Therefore, a one-time etching treatment is enough.

However, the proposed method has a problem in that a final bonding property of the electrolytic Cu plated wiring layer to the resin layer is poorer as compared with the two-layer structure of the Ni bonding layer 12/the Cu seed layer 14.

### [Patent Document 1]

JP-A-2003-218516 Publication

### SUMMARY OF THE INVENTION

It is an object of the invention to provide a wiring board and a method of manufacturing the wiring board in which it is possible to form a wiring layer while maintaining an excellent bonding property to a resin layer without requiring a complicated processing for forming a bonding layer and a seed layer on a resin layer and removing unnecessary portions of both of the layers.

In order to achieve the object, according to a first aspect of the invention, there is provided a wiring board including:

a resin insulating layer;

an Ni—Cu alloy bonding seed layer constituted by 20 to 75 wt % of Ni and Cu to be a residual part formed on the resin insulating layer; and

a Cu wiring layer constituted by Cu formed the Ni—Cu alloy bonding seed layer.

According to a second aspect of the invention, there is provided a method of manufacturing the wiring board according to the first aspect, including the steps of:

forming the Ni—Cu alloy bonding seed layer over a whole surface of a region on the resin insulating layer where a wiring layer is to be formed;

forming a plated resist pattern on the bonding seed layer;

forming a Cu wiring layer through electrolytic plating in an opening portion of the plated resist pattern by using the bonding seed layer as a feeding layer;

removing the plated resist pattern; and

removing the bonding seed layer in a portion exposed by the removal of the plated resist pattern.

According to a third aspect of the invention, there is provided a method of manufacturing the wiring board according to the first aspect, including the steps of:

forming the Ni—Cu alloy bonding seed layer over a whole surface of a region on the resin insulating layer where a wiring layer is to be formed;

forming a Cu wiring layer over a whole surface of the bonding seed layer;

forming an etching resist pattern on the Cu wiring layer;

forming a wiring layer with being pattered in a lump by etching the Cu wiring layer and the bonding seed layer thereunder by using the etching resist pattern as a mask; and

removing the etching resist pattern.

Further, in order to achieve the object, according to a forth aspect of the invention, there is provided a wiring board having a resin insulating layer and a wiring layer formed thereon, wherein

the wiring layer is formed by an Ni—Cu alloy constituted by 20 to 75 wt % of Ni and Cu to be a residual part over a whole thickness of the wiring layer.

According to a fifth aspect of the invention, there is provided a method of manufacturing the wiring board according to the third aspect, including the steps of:

forming a metal layer of the Ni—Cu alloy over a whole surface of a region on the resin insulating layer where a wiring layer is to be formed;

forming an etching resist pattern on the metal layer;

patterning the metal layer of the Ni—Cu alloy through etching to form the wiring layer by using the etching resist pattern as a mask; and

removing the etching resist pattern.

According to the first invention, a seed layer serving as a bonding layer, that is, the bonding seed layer is formed with the Ni—Cu alloy within a predetermined composition range. Consequently, the formation of the bonding layer and the seed layer and the removal of the unnecessary portions of both of the layers can be carried out through a one-time treatment, respectively. At the same time, it is possible to maintain an excellent bonding property of the wiring layer to the resin layer.

According to the second invention, the wiring layer itself is directly formed on the resin through the Ni—Cu alloy within the predetermined composition range. Consequently, it is possible to form the wiring layer through a one-time treatment while maintaining an excellent bonding property to the resin layer without separately requiring the formation of the bonding layer and the seed layer and the removal of the unnecessary portions of both of the layers.

### BRIEF DESCRIPTION OF THE DRAWINGS

FIG. 1 is a sectional view typically showing a method of forming an electrolytic Cu plated wiring layer using a conventional Ni bonding layer/Cu seed layer.

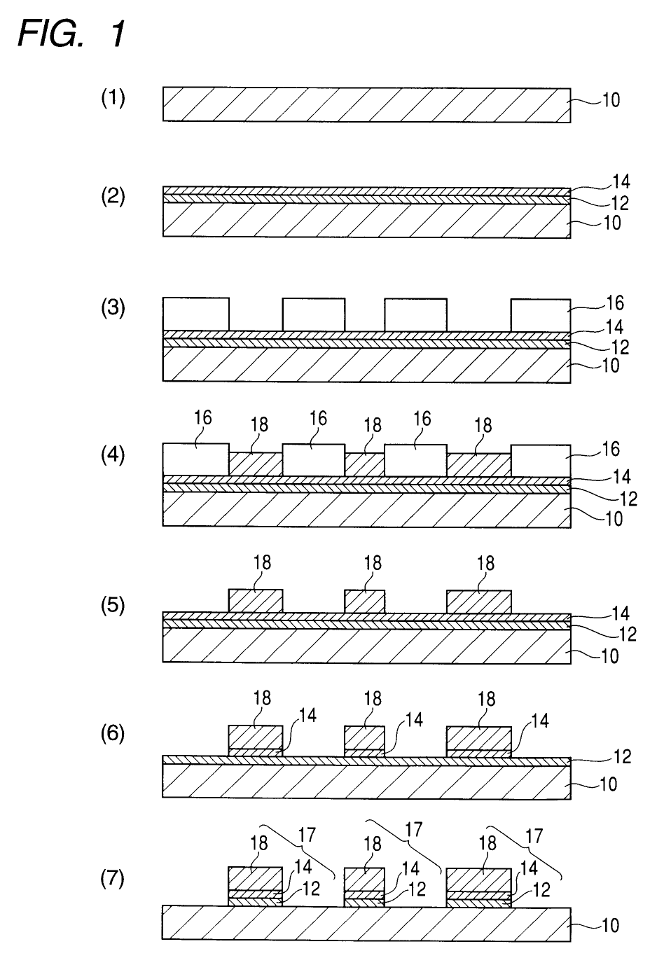

FIG. 2A is a sectional view typically showing a method of forming a wiring layer having an Ni—Cu alloy bonding seed layer and an electrolytic Cu plated layer formed thereon on a resin layer by an embodiment according to a first invention.

FIG. 2B is a sectional view typically showing a method of forming a wiring layer having an Ni—Cu alloy bonding seed layer and an electrolytic Cu plated layer formed thereon on a resin layer by another embodiment according to a first invention.

FIG. 3 is a sectional view typically showing a method of directly forming an Ni—Cu alloy wiring layer on a resin layer according to a second invention.

FIG. 4 is a graph showing a relationship between a peel strength of the electrolytic Cu plated wiring layer formed according to the first invention and an Ni content of the Ni—Cu alloy bonding seed layer.

### DETAILED DESCRIPTION OF THE PREFERRED EMBODIMENTS

### Embodiment 1A

Description will be given to an example of a desirable embodiment for fabricating a wiring board according to a first invention.

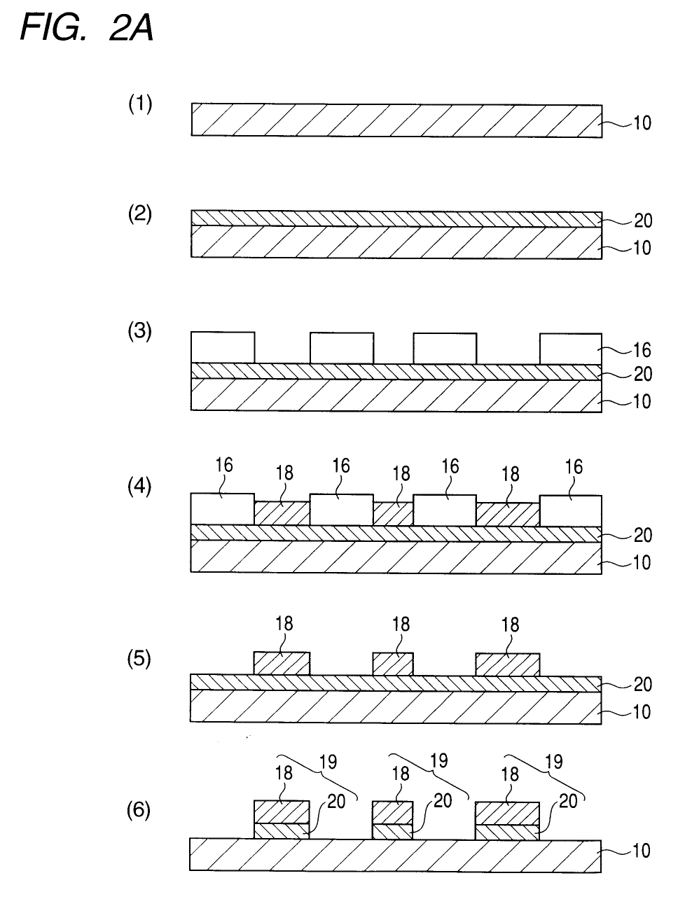

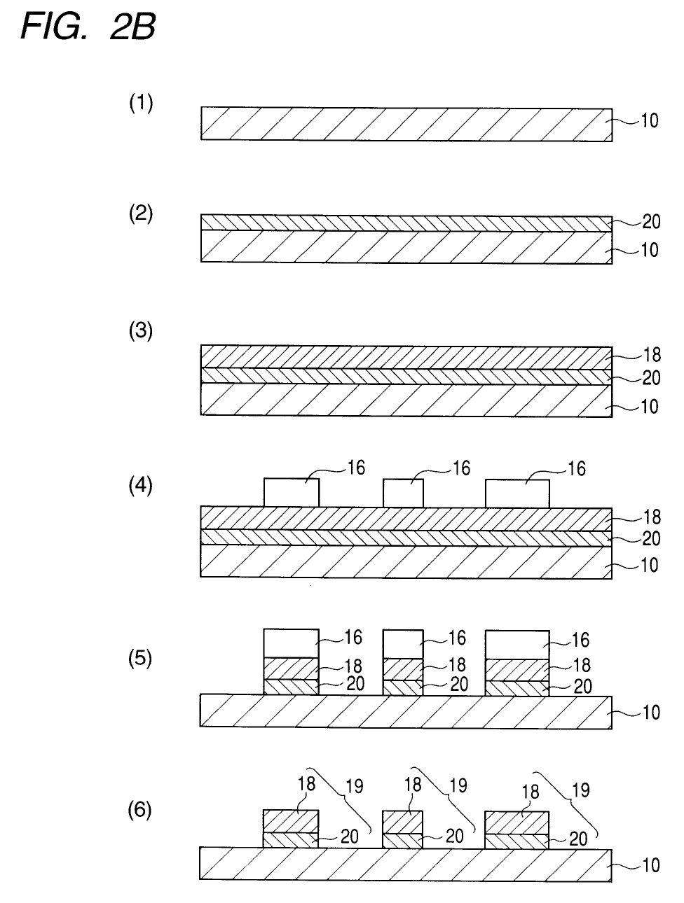

As shown in FIG. 2A(1), a resin layer 10 constituted by epoxy or polyimide having a thickness of approximately 50 μm is prepared as an interlayer insulating film of a wiring board.

As shown in FIG. 2A(2), a resin surface is cleaned with an argon plasma of approximately 0.5 Pa and a bonding seed layer 20 constituted by an Ni—Cu alloy having a specified composition according to the invention is formed through sputtering in an argon gas atmosphere of approximately 0.5 Pa with a vacuum held. The bonding seed layer 20 generally has a thickness of approximately 500 nm and desirably has a thickness of approximately 100 to 1000 nm in consideration of the case in which a concavo-convex portion is formed on the resin surface.

As shown in FIG. 2A(3), a plated resist pattern 16 is formed on the Ni—Cu alloy bonding seed layer 20 through a photoresist application, a pattern exposure and a development.

As shown in FIG. 2A(4), electrolytic Cu plating is carried out by using the Ni—Cu alloy bonding seed layer 20 as a feeding layer, and an electrolytic Cu plated layer 18 having a thickness of approximately 20 μm is formed on the Ni—Cu alloy bonding seed layer 20 exposed into an opening of the plated resist pattern 16.

As shown in FIG. 2A(5), the plated resist pattern 16 is peeled and removed.

As shown in FIG. 2A(6), the Ni—Cu alloy bonding seed layer 20 in an unnecessary portion exposed through the peeling of the plated resist pattern 16 is removed with a sulfuric acid based solution to be a Cu etchant. As compared with the thickness of the Ni—Cu alloy bonding seed layer 20, the thickness of the electrolytic Cu plated layer 18 is greater. Therefore, there is no drawback that a disconnection is caused by the etching. Consequently, there is finished a wiring layer 19 in a predetermined pattern which is typically constituted by the seed layer 20 and the electrolytic Cu plated layer 18 in a line and space (L/S)=20 μm/20 μm. Finally, an insulating property between the wiring patterns is confirmed so that the wiring forming process is completed.

According to the embodiment, the bonding seed layer serving as a bonding layer and a seed layer can be formed on the resin layer through the one-time treating step, the unnecessary portions of both of the layers can also be removed through the one-time etching treatment, and at the same time, it is possible to maintain an excellent bonding property of the electrolytic copper plated wiring layer to the resin layer.

### Embodiment 1B

Description will be given to another example of a desirable embodiment for fabricating a wiring board according to the first invention.

As shown in FIG. 2B(1), a resin layer 10 constituted by epoxy or polyimide having a thickness of approximately 50 μm is prepared as an interlayer insulating film of a wiring board.

As shown in FIG. 2B(2), a resin surface is cleaned with an argon plasma of approximately 0.5 Pa and a bonding seed layer 20 constituted by an Ni—Cu alloy having a specified composition according to the invention is formed through sputtering in an argon gas atmosphere of approximately 0.5 Pa with a vacuum held. The bonding seed layer 20 has a thickness of approximately 500 nm, for example. However, in considering a case that asperity is formed on a resin surface, it is desirable that the bonding seed layer 20 has a thickness of approximately 100 to 1000 nm. The above-mentioned processes are the same as in Embodiment 1A, and following processes are different.

As shown in FIG. 2B(3), electrolytic Cu plating is carried out by using the Ni—Cu alloy bonding seed layer 20 as a feeding layer, and an electrolytic Cu plated layer 18 having a thickness of approximately 20 μm is formed on the Ni—Cu alloy bonding seed layer 20.

As shown in FIG. 2B(4), an etching resist pattern 16 is formed through a photoresist application, a pattern exposure and a development.

As shown in FIG. 2B(5), an electrolytic Cu plated layer 18 exposed into an opening of the plated resist pattern 16 and the Ni—Cu alloy bonding seed layer 20 thereunder are removed in a lump with a sulfuric acid based solution to be a Cu etchant.

As shown in FIG. 2B(6), the etching resist pattern 16 is peeled. Consequently, there is finished a wiring layer 19 in a predetermined pattern which is typically constituted by the bonding seed layer 20 and the electrolytic Cu plated layer 18 in a line and space (L/S)=20 μm/20 μm. Finally, an insulating property between the wiring patterns is confirmed so that the wiring forming process is completed.

According to the embodiment, the bonding seed layer serving as a bonding layer and a seed layer can be formed on the resin layer through the one-time treating step, the bonding seed layer and the electrolytic Cu plated layer thereon can also be patterned through the one-time etching treatment to form a wiring layer constituted by both layers, and at the same time, it is possible to maintain an excellent bonding property of the wiring layer to the resin layer.

In the embodiment, in the processes shown by FIG. 2B(3), the electrolytic Cu plated layer 18 having a thickness of approximately 20 μm is formed. In stead of the electrolytic Cu plated layer, for example, the Cu layer 18 having a thickness of approximately 2000 nm may be formed. The other processes are not changed by this change.

In the above modified embodiment, it is possible to form the Ni—Cu alloy bonding seed layer 20 shown in FIG. 2B(2) and the Cu layer 18 shown in FIG. 2B(3) in the same sputtering apparatus. Then, it is possible to simplify the whole of the wiring forming processes.

### Embodiment 2

Description will be given to an example of a desirable embodiment for fabricating a wiring board according to a second invention.

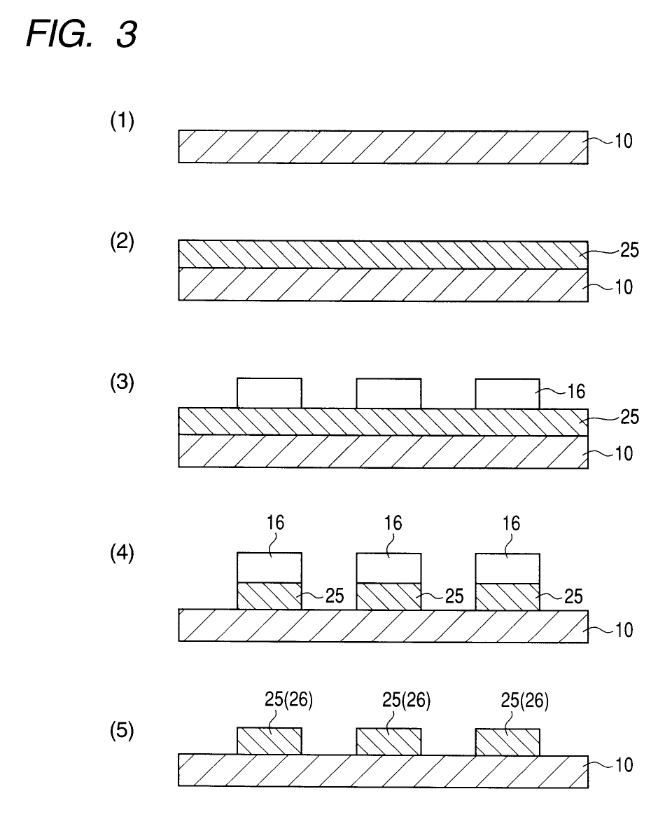

As shown in FIG. 3(1), a resin layer 10 constituted by epoxy or polyimide having a thickness of approximately 50 μm is prepared as an interlayer insulating film of a wiring board.

As shown in FIG. 3(2), a resin surface is cleaned with an argon plasma of approximately 0.5 Pa and a metal layer 25 constituted by an Ni—Cu alloy having a specified composition according to the invention is formed through sputtering in an argon gas atmosphere of approximately 0.5 Pa with a vacuum held. The metal layer 25 has a thickness of approximately 2000 nm, for example.

As shown in FIG. 3(3), an etching resist pattern 16 is formed on the metal layer 25 through a photoresist application, a pattern exposure and a development.

As shown FIG. 3(4), a portion of the metal layer 25 which is exposed from the etching resist pattern 16 is removed with a sulfuric acid based solution to be a Cu etchant.

As shown in FIG. 3(5), the etching resist pattern 16 is peeled. Consequently, there is finished a wiring layer 26 in a predetermined pattern which is typically constituted by the Ni—Cu alloy 25 in a line and space (L/S)=20 μm/20 μm. Finally, an insulating property between the wiring patterns is confirmed so that the wiring forming process is completed.

According to the embodiment, it is possible to directly form, on the resin layer, the wiring layer constituted by the Ni—Cu alloy without requiring separate bonding and seed layers. Therefore, it is possible to maintain an excellent bonding property of the wiring layer to the resin layer while simplifying the wiring board manufacturing process very greatly.

### EXAMPLE

According to the method in accordance with the first embodiment, Ni—Cu alloy bonding seed layers having various compositions are formed on a resin layer and an electrolytic Cu wiring layer is formed thereon to measure a peel strength. A measuring sample is fabricated in the following procedures (1) to (5).

(1) An epoxy resin having a thickness of approximately 50 μm is provided as an interlayer insulating film on a printed board having a copper foil bonded by pressure.

(2) A resin surface is cleaned in an argon gas plasma of approximately 0.5 Pa.

(3) Ni—Cu alloy films (bonding seed layers) having various compositions are formed in a thickness of 500 nm through sputtering in an argon gas atmosphere of approximately 0.5 Pa with a vacuum held in the (2).

(4) An electrolytic Cu plated film is formed in a thickness of 20 μm on the Ni—Cu alloy film.

(5) An etching resist pattern is formed on the Ni—Cu alloy film through a photoresist application, a pattern exposure and a development using a sodium carbonate solution, and the Ni—Cu alloy film is subjected to etching and the etching resist pattern is peeled and removed so that a wiring layer constituted by an electrolytic Cu plated film having a width of 1 cm is formed.

Next, a peel strength test is conducted for the wiring layer obtained as described above.

In the test, the board is fixed to a stage of a tension testing machine and the electrolytic Cu plated film having a width of 1 cm (the wiring layer) is pulled in a perpendicular direction, and a tension obtained in the generation of peeling from the resin layer is measured as a peel strength.

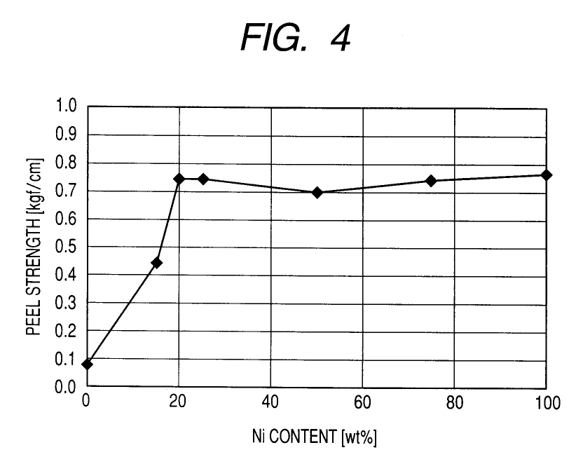

FIG. 4 shows a relationship between an Ni content of the Ni—Cu alloy film (the bonding seed layer) and a peel strength. A state in an Ni content of 100 wt % shown on a right end of FIG. 4 corresponds to the peel strength in case of a conventional Ni bonding layer/Cu seed layer.

As shown in FIG. 4, a peel strength of 0.70 to 0.77 kgf/cm is obtained when the Ni content is equal to or higher than 20 wt %. This is an excellent value which is equivalent to a peel strength in the case in which the conventional Ni bonding layer/Cu seed layer is used.

In observation of a peeling configuration, in the case in which the Ni content is lower than 20 wt %, the peeling is generated on an interface between the electrolytic Cu plated film and the Ni—Cu alloy film. In this case, the peeling is small. On the other hand, in the case in which the Ni content is equal to or higher than 20 wt %, the peeling is wholly caused by coagulation and peeling in the resin layer and the peel strength is determined by a breaking strength of the resin layer itself. Therefore, it is possible to stably obtain a high peel strength. The peeling configuration is the same as that in the case in which the conventional Ni bonding layer/Cu seed layer is used.

When the Ni content exceeds 75 wt %, it is hard to carry out the etching with the sulfuric acid based solution to be the Cu etchant. Accordingly, it is suitable that the Ni content should be approximately 20 to 75 wt %.

Besides, in the present invention, a material of the resin layer is not limited to epoxy nor polyimide.

According to the invention, it is possible to provide a wiring board and a method of manufacturing the wiring board in which it is possible to form a wiring layer while maintaining an excellent bonding property to a resin layer without requiring a complicated processing for forming a bonding layer and a seed layer on a resin layer and removing unnecessary portions of both of the layers.

According to the first invention, particularly, the bonding seed layer serving as the bonding layer and the seed layer can be formed on the resin layer through the one-time treating step and the unnecessary portions of both of the layers can also be removed through the one-time etching treatment, and at the same time, it is possible to maintain an excellent bonding property of the electrolytic copper plated wiring layer to the resin layer.

According to the second invention, furthermore, it is possible to directly form the wiring layer constituted by the Ni—Cu alloy on the resin layer without requiring separate bonding and seed layers. Therefore, it is possible to maintain an excellent bonding property of the wiring layer to the resin layer while simplifying the wiring board manufacturing process very greatly.

What is claimed is:

1. A wiring board comprising:
a resin insulating layer;
an Ni—Cu alloy bonding seed layer constituted by 20 to 75 wt % of Ni and Cu to be a residual part formed on the resin insulating layer; and
a Cu wiring layer constituted by Cu formed on the Ni—Cu alloy bonding seed layer.

2. A method of manufacturing the wiring board according to claim 1, comprising the steps of:
forming the Ni—Cu alloy bonding seed layer over a whole surface of a region on the resin insulating layer where a wiring layer is to be formed;
forming a plated resist pattern on the bonding seed layer;
forming a Cu wiring layer through electrolytic plating in an opening portion of the plated resist pattern by using the bonding seed layer as a feeding layer;
removing the plated resist pattern; and
removing the bonding seed layer in a portion exposed by the removal of the plated resist pattern.

3. A method of manufacturing the wiring board according to claim 1, comprising the steps of:
forming the Ni—Cu alloy bonding seed layer over a whole surface of a region on the resin insulating layer where a wiring layer is to be formed;
forming a Cu wiring layer over a whole surface of the bonding seed layer;
forming an etching resist pattern on the Cu wiring layer;
forming a wiring layer with being pattered in a lump by etching the Cu wiring layer and the bonding seed layer thereunder by using the etching resist pattern as a mask; and
removing the etching resist pattern.

4. A wiring board having a resin insulating layer and a wiring layer formed thereon, wherein
the wiring layer is formed by an Ni—Cu alloy constituted by 20 to 75 wt % of Ni and Cu to be a residual part over a whole thickness of the wiring layer.

5. A method of manufacturing the wiring board according to claim 3, comprising the steps of:
forming a metal layer of the Ni—Cu alloy over a whole surface of a region on the resin insulating layer where a wiring layer is to be formed;
forming an etching resist pattern on the metal layer;
patterning the metal layer of the Ni—Cu alloy through etching to form the wiring layer by using the etching resist pattern as a mask; and
removing the etching resist pattern.
